(19) United States
(12) Patent Application Publication
(10) Pub. No.: US 2012/0152343 A1
(43) Pub. Date: Jun. 21, 2012

(54) ALUMINUM PASTE COMPOSITIONS COMPRISING SILOXANES AND THEIR USE IN MANUFACTURING SOLAR CELLS

(75) Inventors: LAPKIN K. CHENG, BEAR, DE (US); MARK GERRIT ROELOFS, EARLEVILLE, MD (US)

(73) Assignee: E. I. DU PONT DE NEMOURS AND COMPANY, Wilmington, DE (US)

(21) Appl. No.: 12/969,951

(22) Filed: Dec. 16, 2010

(51) Int. Cl. H01L 31/0224; H01L 31/18; H01B 1/22

(52) U.S. Cl. 136/256; 252/512; 438/98; 257/E31.124

(57) ABSTRACT

Disclosed are aluminum paste compositions, processes to form solar cells using the aluminum paste compositions, and the solar cells so-produced. The low-siloxane aluminum paste compositions consist essentially of 0.005-2.6%, by weight of at least one siloxane; 44.5-84.9%, by weight of an aluminum powder; 0.05-5.8% of an optional indium-free additive; and 15-50%, by weight of an organic vehicle, wherein the amounts in % by weight are based on the total weight of the aluminum paste composition. The high-siloxane aluminum paste compositions comprise 15-68%, by weight of at least one siloxane; 25-84.9%, by weight of an aluminum powder; 0.1-10%, by weight of an organic vehicle.

### FIELD OF THE INVENTION

The present invention relates to aluminum paste compositions and their use as back-side pastes in the manufacture of solar cells.

### TECHNICAL BACKGROUND

Currently, most electric power-generating solar cells are silicon solar cells. A conventional silicon solar cell structure has a large area p-n junction made from a p-type silicon wafer, a negative electrode that is typically on the front-side or sun-side of the cell, and a positive electrode on the back-side. It is well-known that radiation of an appropriate wavelength falling on a p-n junction of a semiconductor body serves as a source of external energy to generate hole-electron pairs in that body. The potential difference that exists at a p-n junction causes holes and electrons to move across the junction in opposite directions and thereby gives rise to flow of an electric current that is capable of delivering power to an external circuit.

Process flow in mass production of solar cells is generally aimed at achieving maximum simplification and minimization of manufacturing costs. Electrodes are typically made using methods such as screen printing from a metal paste. During the formation of a silicon solar cell, an aluminum paste is generally screen printed and dried on the back-side of the silicon wafer. The wafer is then fired at a temperature above the melting point of aluminum to form an aluminum-silicon melt. Subsequently, during the cooling phase, an epitaxially grown layer of silicon is formed that is doped with aluminum. This layer is generally called the back surface field (BSF) layer or p+ layer, and helps to improve the energy conversion efficiency of the solar cell. However, due to lack of high quality passivation layer, the current state-of-the-art cells still suffer from recombination of photogenerated carriers, either within the BSF layer, or at the back surface of the cell. This loss of photo-generated carriers leads to a loss in efficiency.

Hence, there is a need for back-side aluminum paste compositions and methods of making solar cells using the back-side aluminum paste compositions to improve efficiency of the solar cells.

### SUMMARY

Disclosed are aluminum paste compositions consisting essentially of:

a) 0.005-2.6%, by weight of at least one siloxane;

(b) 44.5-84.9%, by weight of an aluminum powder, such that the weight ratio of aluminum powder to siloxane is in the range of about 30:1 to about 10,000:1;

(c) 0.01-6.8%, by weight of an optional indium-free additive, wherein the optional indium-free additive comprises lead-free glass frit, amorphous silicon dioxide, organometallic compounds, boron-containing compounds, metal salts, or mixtures thereof; and

(d) 15-50%, by weight of an organic vehicle,

wherein the amounts in % by weight are based on the total weight of the aluminum paste composition.

Also disclosed herein are processes for forming a silicon solar cell, comprising:

(a) applying an aluminum paste on a back-side of a p-type silicon substrate, the aluminum paste consisting essentially of 0.005-2.6%, by weight of a siloxane; 44.5-84.9%, by weight of an aluminum powder, such that the weight ratio of aluminum powder to siloxane is in the range of about 30:1 to about 10,000:1; 0.01-6.8%, by weight of an optional indium-free additive, wherein the optional indium-free additive comprises lead-free glass frit, amorphous silicon dioxide, organometallic compounds, boron-containing compounds, metal salts, or mixtures thereof; and 15-50%, by weight of an organic vehicle, wherein the amounts in % by weight are based on the total weight of the aluminum paste composition;

(b) applying a metal paste on a front-side of the p-type silicon substrate, the front-side being opposite to the back-side; and

(c) firing the p-type silicon substrate after the application of both the aluminum paste and the metal paste to a peak temperature of Tₘₐₓ in the range of 600-980° C., such that the substrate is fired at the temperature range of (Tₘₐₓ-100)−Tₘₐₓ for 0.4-30 sec.

Also disclosed herein are aluminum paste compositions comprising:

(a) 15-68%, by weight of at least one siloxane;

(b) 25-84.9%, by weight of an aluminum powder;

(c) 0.1-10%, by weight of an organic vehicle,

wherein the amounts in % by weight are based on the total weight of the aluminum paste composition.

Also dislosed herein are processes of forming a silicon solar cell comprising:

(a) applying an aluminum paste on a back-side of a p-type silicon substrate, the aluminum paste comprising 15-68%, by weight of a siloxane; 25-84.9%, by weight of an aluminum powder; and 0.1-10%, by weight of an organic vehicle, wherein the amounts in % by weight are based on the total weight of the aluminum paste composition;

(b) applying a metal paste on a front-side of the p-type silicon substrate, the front-side being opposite to the back-side; and

(c) firing the p-type silicon substrate after the application of both the aluminum paste and the metal paste to a peak temperature of Tₘₐₓ in the range of 600-980° C., such that the substrate is fired at the temperature range of (Tₘₐₓ-100)−Tₘₐₓ for 0.4-30 sec.

### BRIEF DESCRIPTION OF THE FIGURES

FIG. 1 schematically illustrates a cross-sectional view of a silicon wafer comprising a p-type region, an n-type region on a front-side, a p-n junction, and a back-side opposite the front-side.

FIG. 2 schematically illustrates a cross-sectional view of a silicon wafer comprising a layer of antireflective coating (ARC) on an n-type region.

FIG. 3 schematically illustrates a cross-sectional view of a silicon wafer comprising a layer of front-side metal paste disposed over an antireflective coating (ARC) layer and an aluminum paste layer disposed on a p-type region.

FIG. 4 schematically illustrates a cross-sectional view of an exemplary solar cell.

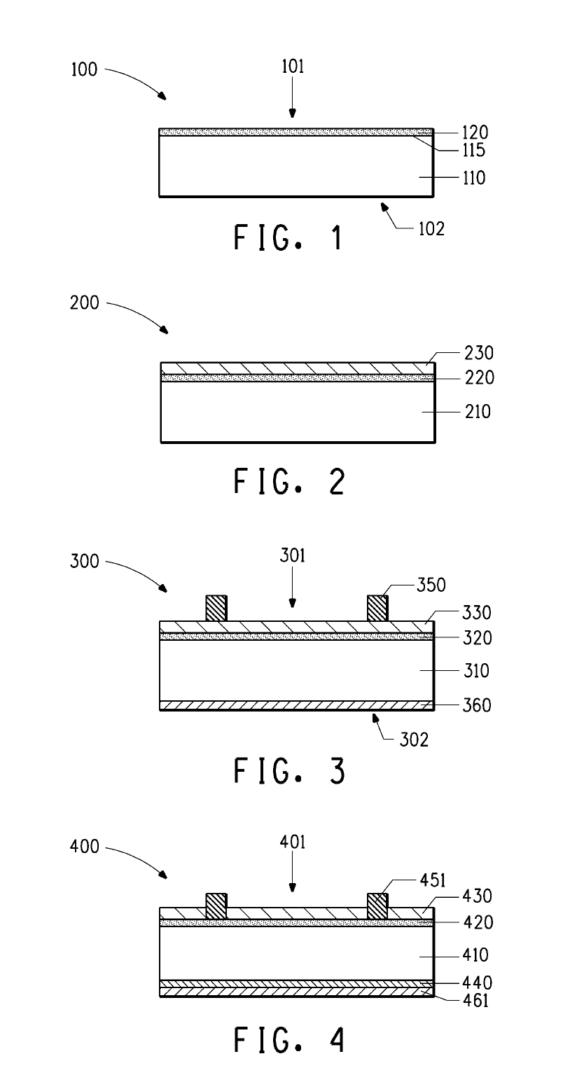

Reference numerals shown in FIGS. 1-4 are explained below:
100, 200, 300: silicon wafer at various stages in the making of a solar cell
400: solar cell
101: front-side of the silicon wafer
401: front-side or the sun-side of the solar cell
102, 302: back-side of the silicon wafer
110, 210, 310, 410: p-type region of the silicon wafer
115: p-n junction
120, 220, 320, 420: n-type region of the silicon wafer
230, 330, 430: antireflective coating (ARC) layer
350: front-side metal paste, for example, silver paste
451: metal front electrode (obtained by firing front-side metal paste)
360: back-side aluminum paste
461: aluminum back electrode (obtained by firing back-side aluminum paste)
440: p+ layer

### DETAILED DESCRIPTION

Disclosed are low-siloxane aluminum paste compositions consisting essentially of at least one siloxane, an aluminum powder, an optional indium-free additive, and an organic vehicle, the optional indium-free additive comprising lead-free glass frit, amorphous silicon dioxide, organometallic compounds, boron-containing compounds, metal salts, and mixtures thereof.

Also, disclosed are high-siloxane aluminum paste compositions comprising at least one siloxane, an aluminum powder, and an organic vehicle.

Suitable siloxanes are oligomers or polymers comprising at least one of a monofunctional “M” unit having the formula, RR′R″SiO_{1/2}; a difunctional “D” unit having the formula, R¹R²SiO_{2/2}; or a trifunctional “T” unit having the formula, R³SiO_{3/2}, where R, R′, R″, R², and R³ denote hydrocarbyl groups or substituted hydrocarbyl groups; and R¹ may be hydrogen or a hydrocarbyl group or a substituted hydrocarbyl group. Different combinations of R, R¹, and R² groups may be chosen such as to make co-polymers.

The oligomeric or polymeric siloxanes can be linear, branched, or cyclic siloxanes. The ends of linear or branched siloxane chains are terminated by monfunctional units M. For example, a linear siloxane is of the formula: M-Dₙ₋₂-M, n being the total number of silicon atoms; a cyclic siloxane has the formula: Dₙ; and a branched siloxane is represented by the formula: TₖDₘM₂₊ₖ, where k (k≧1) is the number of branches; m (m≧0) is the number of difunctional units; and the total number of silicon atoms (n) in the branched siloxane is n=2+2k+m. The total number of silicon atoms, n, in the siloxane is from 2-300, or 2-80, or 10-50.

As used herein, the term “hydrocarbyl” refers to a straight chain, branched or cyclic arrangement of carbon atoms connected by single, double, or triple carbon to carbon bonds, and substituted accordingly with hydrogen atoms. Such hydrocarbyl groups may be aliphatic and/or aromatic. Examples of hydrocarbyl groups include methyl, ethyl, propyl, isopropyl, butyl, isobutyl, t-butyl, cyclopropyl, cyclobutyl, cyclopentyl, methylcyclopentyl, cyclohexyl, methylcyclohexyl, benzyl, phenyl, o-tolyl, m-tolyl, p-tolyl, xylyl, vinyl, allyl, butenyl, cyclohexenyl, cyclooctenyl, cyclooctadienyl, and butynyl. A “substituted hydrocarbyl group,” as defined herein, is a hydrocarbyl group with at least one carbon atom bonded to at least one heteroatom and to at least one hydrogen atom. Substituted hydrocarbyl groups may include ether linkages. “Heteroatoms,” as defined herein, are all atoms other than carbon and hydrogen atoms. Examples of substituted hydrocarbyl groups include toluoyl, chlorobenzyl, fluoroethyl, p-CH₃—S—C₆H₅, 2-methoxy-propyl, and (CH₃)₃SiCH₂.

Suitable siloxanes include poly(dimethylsiloxane), poly(methylhydrogensiloxane), poly(dimethylsiloxane-co-methylphenylsiloxane), and poly(ethylmethylsiloxane-co-(alpha-methylphenylethyl)methylsiloxane).

The siloxane is present in the low-siloxane aluminum paste composition in the range of 0.005-2.6%, or 0.01-1%, or 0.035-0.51%, by weight, based on the total weight of the aluminum paste composition. In another embodiment, the siloxane is present in the high-siloxane aluminum paste composition in the range of 15-68%, or 18-65%, or 20-60%, by weight, based on the total weight of the aluminum paste composition.

As used herein, the term “low-siloxane aluminum paste composition” refers to the aluminum paste composition comprising 0.005-2.6%, by weight of siloxane based on the total weight of the aluminum paste composition; the term “high-siloxane aluminum paste composition” refers to aluminum paste compositions comprising 15-68% siloxane, by weight; and the terms “aluminum paste composition” and “aluminum paste” used interchangeably are meant to include both the low-siloxane aluminum paste composition and the high-siloxane aluminum paste composition.

Suitable aluminum powder includes aluminum particles such as, nodular aluminum, spherical aluminum, flake aluminum, irregularly-shaped aluminum, and any combination thereof. In some embodiments, the aluminum powder has a particle size, d₅₀ of 1 micron to 10 microns, or 2 microns to 8 microns. In some embodiments, the aluminum powder is a mixture of aluminum powders of different particle sizes. For example, aluminum powder having a particle size, d₅₀ in the range of 1 micron to 3 microns can be mixed with an aluminum powder having a particle size, d₅₀ in the range of 5 microns to 10 microns.

The aluminum powder is present in the low-siloxane aluminum paste composition in an amount ranging from 44.5-84.9%, or 54.5-82%, or 64-80% by weight, based on the total weight of the aluminum paste composition. In another embodiment, the aluminum powder is present in the high-siloxane aluminum paste composition in the range of 25-84.9%, or 30-81.9%, or 32-79.9%, by weight, based on the total weight of the aluminum paste composition.

As used herein, the particle sizes refer to cumulative particle size distributions based on volume and assuming spherical particles. Hence, the particle size d₅₀ is the median particle size, such that 50% of the total volume of the sample of particles comprises particles having volume smaller than the volume of a sphere having a diameter of d₅₀.

In an embodiment, the aluminum powders have aluminum content in the range of 99.5-100 wt %. In one embodiment, the aluminum powders further comprise other particulate metal(s), for example silver or silver alloy powders. The proportion of such other particulate metal(s) can be from 0.01-10%, or from 1-9%, by weight, based on the total weight of the aluminum powder including particulate metal(s).

In some embodiments, an optional indium-free additive is present in the aluminum paste composition in the range of 0.01-6.8%, or 0.1-3%, or 0.2-1%, by weight, based on the total weight of the aluminum paste composition.

Suitable optional indium-free additive comprises lead-free glass frit, amorphous silicon dioxide, organometallic compounds, boron-containing compounds, metal salts, and mixtures thereof.

In an embodiment, the aluminum paste composition further includes at least one lead-free glass frit as an inorganic binder. In an embodiment, the lead-free glass frit comprises at least 10% or, at least 20%, or at least 40%, by weight of one of a bismuth oxide, an antimony oxide, or a mixture thereof. The glass frit can comprise components which, upon firing, undergo recrystallization or phase separation and form a frit with a separated phase that has a lower softening point than the original softening point. The softening point (glass transition temperature) of the glass frit can be determined by differential thermal analysis (DTA), and is typically in the range of about 325-800° C.

The lead-free glass frits typically have a particle size, d₅₀ in the range of 0.1-20 microns or 0.5-10 microns. In an embodiment, the lead-free glass frit can be a mixture of two or more lead-free glass frit compositions. In another embodiment, each lead-free glass frit of the mixture of two or more lead-free glass frit compositions can have different particle sizes, d₅₀. The lead-free glass frit can be present in an amount ranging from 0.01-5%, or 0.1-3%, or 0.2-1.5%, by weight, based on the total weight of the aluminum paste composition.

Examples of suitable lead-free glass frits include borosilicate and aluminosilicate glasses. Lead-free glass frits can also comprise one or more oxides, such as B₂O₃, Bi₂O₃, SiO₂, TiO₂, Al₂O₃, CdO, CaO, MgO, BaO, ZnO, Na₂O, Li₂O, Sb₂O₃, PbO, ZrO₂, and P₂O₅.

If present, the amorphous silicon dioxide is in the form of a finely divided powder. The amorphous silicon dioxide powder has a particle size, d₅₀ in the range of 5-1000 nm or 10-500 nm. In some embodiments, the amorphous silicon dioxide is a synthetically produced silica, for example, pyrogenic silica or silica produced by precipitation.

Amorphous silicon dioxide can be present in the aluminum paste composition in the range of 0.01-1.0%, or 0.03-0.7%, or 0.1-0.4%, by weight, based on the total weight of the aluminum paste composition.

As used herein, the organometallic compounds include compounds with metal-carbon bonds and salts containing metal cations and organic anions. Suitable organometallic compounds includes zinc neodecanoate, tin octoate, calcium octoate, and mixtures thereof. The organometallic compound and mixtures thereof can be present in the aluminum paste composition in the range of 0.01-5%, or 0.05-3%, or 0.2-2%, by weight, based on the total weight of the aluminum paste composition.

Suitable boron-containing compounds include boron; boron nitride e.g., amorphous boron nitride, cubic boron nitride, hexagonal boron nitride; borides e.g., calcium hexaboride, aluminum diboride; aluminum-boron alloys containing 0.5-40% boron; borates e.g., sodium borate, calcium borate, potassium borate, magnesium borate; borate esters e.g., triethyl borate, tripropyl borate; boronic acids e.g., 1,3-benzenediboronic acid; organometallic boron compounds, and mixtures thereof. The boron or boron-containing compound is preferably in a weight range such as to provide 0.01-3%, by weight of boron, and more preferably in the range of 0.05-1%, by weight of boron, based on the total weight of the aluminum paste composition.

Specific examples of metal salts include calcium magnesium carbonate, calcium carbonate, calcium oxalate, calcium pyrophosphate, and bismuth phosphate. Each of these metal salts can be present in the aluminum paste composition in the range of 0.01-6.8%, or 0.03-5.0%, or 0.1-3.0%, by weight, based on the total weight of the aluminum paste composition.

The term “Non-OV”, as used herein for the low-siloxane aluminum paste composition includes the at least one siloxane, the aluminum powder, and the optional indium-free additive(s). The total Non-OV content of the low-siloxane aluminum paste composition is in the range of 50-85%, or 70-80%, by weight, based on the total weight of the aluminum paste composition. Furthermore, the Non-OV content of the low-siloxane aluminum paste composition comprises aluminum powder present in an amount of 89-99.99%, or 91.4-99.5%; siloxane present in an amount of 0.01-3% or 0.05-0.6%; and optional indium-free additive present in an amount of 0.1-8%, by weight. Additionally, the weight ratio of aluminum powder to siloxane in the low-siloxane aluminum paste composition is in the range of 30:1 to about 10,000:1 or 152:1 to 2000:1.

In one embodiment, the low-siloxane aluminum paste composition also comprises an organic vehicle present in an amount of 15-50%, or 20-30%, by weight, based on the total weight of the aluminum paste composition. In another embodiment, the organic vehicle is present in the high-siloxane aluminum paste composition in an amount of 0.1-10%, or 5-9%, by weight. The amount of organic vehicle in the aluminum paste composition is dependent on several factors, such as the method to be used in applying the aluminum paste and the chemical constituents of the organic vehicle used. Organic vehicle includes one or more of solvents, binders, surfactants, thickeners, rheology modifiers, and stabilizers to provide one or more of: stable dispersion of insoluble solids; appropriate viscosity and thixotropy for application, in particular, for screen printing; appropriate wettability of the silicon substrate and the paste solids; a good drying rate; and good firing properties. Suitable organic vehicles include organic solvents, organic acids, waxes, oils, esters, and combinations thereof. In some embodiments, the organic vehicle is a nonaqueous inert liquid, an organic solvent, or an organic solvent mixture, or a solution of one or more organic polymers in one or more organic solvents. Suitable organic polymers include ethyl cellulose, ethylhydroxyethyl cellulose, wood rosin, phenolic resins, poly (meth)acrylates of lower alcohols, and combinations thereof. Suitable organic solvents include ester alcohols and terpenes such as alpha- or beta-terpineol and mixtures thereof with other solvents such as kerosene, dibutylphthalate, diethylene glycol butyl ether, diethylene glycol butyl ether acetate, hexylene glycol, high boiling alcohols, and mixtures thereof. The organic vehicle can also comprise volatile organic solvents for promoting rapid hardening after deposition of the aluminum paste on the back-side of the silicon wafer. Various combinations of these and other solvents can be formulated to obtain the desired viscosity and volatility.

The aluminum paste compositions are typically viscous compositions and can be prepared by mechanically mixing the aluminum powder, at least one siloxane, and the optional indium-free additive(s) with the organic vehicle. In one embodiment, the manufacturing method of high shear power mixing—a dispersion technique that is equivalent to the traditional roll milling—is used. In other embodiments, roll milling or other high shear mixing techniques are used.

In various embodiments, the aluminum paste compositions are used in the manufacture of aluminum back electrodes of silicon solar cells or respectively in the manufacture of silicon solar cells.

As used herein, the phrase “silicon solar cell” is used interchangeably with “solar cell”, “cell”, “silicon photovoltaic cell”, and “photovoltaic cell”.

FIGS. 1-4 schematically illustrate a process of forming a silicon solar cell in accordance with various embodiments of this invention. The process of forming a silicon solar cell comprises providing a p-type silicon wafer 100. The silicon wafer can be a monocrystalline silicon wafer or a polycrystalline silicon wafer. The silicon wafer 100 can have a thickness from 100-300 microns. As shown in FIG. 1, the silicon wafer 100 includes a p-type region 110 including p-type dopants, an n-type region 120 including n-type dopants, a p-n junction 115, a front-side 101 or the sun-side, and a back-side 102 opposite the front-side 101. The front-side 101 is also termed the sun-side as it is the light-receiving face (surface) of the solar cell. Conventional cells have the p-n junction close to the sun-side and have a junction depth in the range of 0.05-0.5 microns.

In one embodiment, the process of forming a silicon solar cell further comprises forming a layer of optional antireflective coating (ARC) 230 on the n-type region 220 of the silicon wafer 200, as shown in FIG. 2. Any suitable method can be used for the deposition of the antireflective coating, such as chemical vapor deposition (CVD) or plasma enhanced chemical vapor deposition (PECVD). Suitable examples of antireflective coating (ARC) materials include silicon nitride (SiNₓ), titanium oxide (TiOₓ), and silicon oxide (SiOₓ.

The process of forming a silicon solar cell also comprises providing an aluminum paste composition as disclosed hereinabove.

The process of forming a silicon solar cell further comprises applying the aluminum paste on the back-side of a p-type silicon wafer. For example, FIG. 3 shows an aluminum paste layer 360 disposed on the p-type region 310 disposed on the back-side 302 of a silicon wafer 300. The aluminum paste compositions can be applied such that the wet weight (i.e., weight of the solids and the organic vehicle) of the applied aluminum paste is in the range of 4-9.5 mg/cm² or 5.5-8 mg/cm², and the corresponding dry weight of the aluminum paste is the range of 2-7 mg/cm² or 2.5-6 mg/cm². Any suitable method can be used for the application of aluminum paste, such as silicone pad printing or screen printing. In various embodiments, the application viscosity of the aluminum paste compositions as disclosed hereinabove is in the range of 20-200 Pa·s, or 30-150 Pa·s, or 50-120 Pa·s. After the application of the back-side aluminum paste 360 to the back-side 302 of the silicon wafer 300, it may be dried, for example, for a period of 1-120 min, or 2-90 min, or 5-60 min at a temperature in the range of 100-175° C. Alternately, the silicon wafer 300 may be dried at a temperature in the range of 175-350° C. for 5-600 sec, or 10-450 sec, or 15-300 sec. In one embodiment, the high-siloxane aluminum pastes are dried slowly by first ramping the temperature from room temperature to a drying temperature in the range of 100-200° C. at a ramp-rate in the range of 2-50° C./min and then holding the temperature constant at the drying temperature for 1-60 min. Any suitable method can be used for drying, including, for example making use of belt, rotary or stationary driers, in particular, IR (infrared) belt driers. The actual drying time and drying temperature depend on various factors, such as aluminum paste composition, thickness of the aluminum paste layer, and drying method. For example, for the same aluminum paste composition, the temperature range for drying in a box furnace can be in the range of 100-200° C., while for a belt furnace it can be in the range of 150-400° C.

The process of forming a silicon solar cell further comprises applying a front-side metal paste on the antireflective coating disposed on the front-side of the silicon wafer followed by drying. For example, FIG. 3 shows a layer of front-side metal paste 350 disposed over the antireflective coating (ARC) layer 330 on the front-side 301 of the silicon wafer 300. Suitable front-side metal pastes 350 include silver paste. In some embodiments, the steps of drying the back-side aluminum paste 360 and the front-side metal paste 350 are done in a single step. In other embodiments, the steps of drying the back-side aluminum paste 360 and the front-side metal paste 350 are done sequentially following each step of application.

The process of forming a silicon solar cell further comprises firing the silicon wafer with front-side metal paste and back-side aluminum paste at a peak temperature of Tₘₐₓ in the range of 600-980° C., such that the substrate is fired at the temperature range of (Tₘₐₓ-100)−Tₘₐₓ for 0.4-30 sec, or 1-20 sec, or 1.5-10 sec, to form a solar cell, such as solar cell 400 shown in FIG. 4. In some cases, the step of firing is done after the application of both the back-side aluminum paste and the front-side metal paste, such that both the front-side metal paste and the back-side aluminum paste are fired in one step. In an embodiment, one of the drying step, either the drying of the back-side aluminum paste or the drying of the front-side metal paste is done along with the firing step. The firing of the back-side aluminum paste and the front-side metal paste results in the formation of an aluminum back electrode and a metal front electrode such as, aluminum back electrode 461 and metal front electrode 451 as shown in FIG. 4.

During the firing process, the molten aluminum from the back-side aluminum paste 360 dissolves a portion of the silicon of the p-type region 310 and on cooling forms a p+ layer that epitaxially grows from the p-type region 310 of the silicon wafer 300, forming a p+ layer comprising a high concentration of aluminum dopant. In addition, a portion of the molten aluminum-silicon melt forms a continuous layer of the eutectic composition (approximately 12% Si and 88% Al) disposed between the p+ layer and the remaining aluminum particles. Thus the aluminum back electrode 461 may comprise a eutectic layer (not shown) in contact with the p+ layer 440 and an outer layer of particulate aluminum. For example, FIG. 4 shows a p+ layer 440 disposed on the p-type region 410 and the aluminum back electrode 461 disposed at the surface of the p+ layer 440. The p+ layer 440 is also called the back surface field layer, and helps to improve the energy conversion efficiency of the solar cell 400.

Firing is performed, for example, for a period of 10 sec-5 min at a peak temperature of Tₘₐₓ in the range of 500-980° C., such that the substrate is fired at the temperature range of (Tₘₐₓ-100)−Tₘₐₓ for 0.4-30 sec, or 1-20 sec, or 1.5-10 sec. Firing can be carried out using single or multi-zone belt furnaces, in particular, multi-zone IR belt furnaces. Firing is generally carried out in the presence of oxygen, in particular, in the presence of air. During firing, the organic substances, including non-volatile organic materials and the organic portions not evaporated during the optional drying step, are substantially removed, i.e., burned away and/or carbonized. The organic substances removed during firing comprise organic solvent(s), optional organic polymer(s), optional organic additive(s), and the organic moieties of the one or more optional organometallic compounds. If present, the alkaline earth organometallic compounds typically remains as an alkaline earth oxide and/or hydroxide after firing.

In some embodiments, a back-side silver or silver/aluminum paste (not shown) is applied over the back-side aluminum paste 360 and fired at the same time, becoming a silver or silver/aluminum back electrode (not shown). During firing, the boundary between the back-side aluminum and the back-side silver or silver/aluminum assumes an alloy state. The aluminum electrode accounts for most areas of the back electrode, owing in part to the need to form a p+ layer 440. Since soldering to an aluminum electrode is difficult, a silver or silver/aluminum back electrode is formed over portions of the back-side (often as 2-6 mm wide busbars) as an electrode for interconnecting solar cells by means of pre-soldered copper ribbon or the like.

In addition, during the firing process, the front-side metal paste 350 can sinter and penetrate through the antireflective coating layer 330, and is thereby able to electrically contact the n-type region 320. This type of process is generally called “firing through”. This fired-through state is apparent in the metal front electrode 451 of FIG. 4.

FIG. 4 schematically illustrates a cross-sectional view of an exemplary solar cell 400 formed by the process disclosed hereinabove. As shown in FIG. 4, the solar cell 400 comprises a p-type silicon substrate that includes a p-type region 410 sandwiched between an n-type region 420 and a p+ layer 440, wherein the p+ layer 440 comprises silicon doped with aluminum. The p-type silicon substrate is either a single crystalline silicon substrate or a polycrystalline silicon substrate. The solar cell 400 also includes an aluminum back electrode 461 disposed on the p+ layer 440. In some embodiments, the aluminum can be present in the aluminum back electrode 461 in the range of 92-99.99%, or 97-99.95%, by weight, based on the total weight of the aluminum back electrode 461. In an embodiment, the aluminum back electrode 461 comprises 0.1-8%, by weight of optional indium-free additive, e.g., lead-free glass frits, amorphous silicon dioxide, metal oxides formed as a result of the decomposition of organometallic compounds, boron-containing compounds and their decomposition products, metal salts, and mixtures thereof.

As shown in FIG. 4, the front-side or the sun-side 401 of the solar cell 400 further comprises a metal front electrode 451 disposed on a portion of the n-type region 420 and an antireflective coating (ARC) layer 430 disposed on another portion of the n-type region, wherein another portion is the portion of the n-type region not covered by the metal front electrode 451.

In some embodiments, the use of the hereinabove disclosed aluminum paste compositions comprising at least one siloxane in the production of aluminum back electrodes of silicon solar cells can result in silicon solar cells exhibiting improved cell efficiency (E_{ff}), as compared to solar cells formed using aluminum paste without any siloxane as an additive.

As used herein, the terms “comprises,” “comprising,” “includes,” “including,” “has,” “having” or any other variation thereof, are intended to cover a non-exclusive inclusion. For example, a composition, process, method, article, or apparatus that comprises a list of elements is not necessarily limited to only those elements but may include other elements not expressly listed or inherent to such composition, process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), or both A and B is true (or present).

As used herein, the phrase “one or more” is intended to cover a non-exclusive inclusion. For example, one or more of A, B, and C implies any one of the following: A alone, B alone, C alone, a combination of A and B, a combination of B and C, a combination of A and C, or a combination of A, B, and C.

Also, use of “a” or “an” are employed to describe elements and described herein. This is done merely for convenience and to give a general sense of the scope of the invention. This description should be read to include one or at least one and the singular also includes the plural unless it is obvious that it is meant otherwise.

Unless otherwise defined, all technical and scientific terms used herein have the same meaning as commonly understood by one of ordinary skill in the art to which this invention belongs. Although methods and materials similar or equivalent to those described herein can be used in the practice or testing of embodiments of the disclosed compositions, suitable methods and materials are described below.

In the foregoing specification, the concepts have been disclosed with reference to specific embodiments. However, one of ordinary skill in the art appreciates that various modifications and changes can be made without departing from the scope of the invention as set forth in the claims below.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all embodiments.

It is to be appreciated that certain features are, for clarity, described herein in the context of separate embodiments, may also be provided in combination in a single embodiment. Conversely, various features that are, for brevity, described in the context of a single embodiment, may also be provided separately or in any subcombination. Further, reference to values stated in ranges includes each and every value within that range.

The concepts disclosed herein will be further described in the following examples, which do not limit the scope of the invention described in the claims.

The examples cited here relate to aluminum paste compositions used to form back-side contact in conventional solar cells.

The aluminum paste compositions can be used in a broad range of semiconductor devices, although they are especially effective in light-receiving elements such as photodiodes and solar cells. The discussion below describes how a solar cell is formed using the aluminum paste composition(s) disclosed herein, and how the solar cell is tested for cell electrical characteristics such as, cell efficiency.

Unless specified otherwise, compositions are given as weight percents.

### EXAMPLES

### Preparation of Back-Side Aluminum Paste Compositions

250 g to 1000 g of master batch (MB) aluminum pastes A1, A2, B, C, D, and E were first made and small portions were taken out from the master batches to prepare exemplary pastes comprising various siloxanes.

### Preparation of Master Batch Aluminum Paste A2

First, a pre-wet aluminum slurry (PWAS) was made by mixing 80% of air-atomized nodular aluminum powder (having average particle size of 6.9 microns) and 20% of organic vehicle 1 (OV1), by weight. OV1 included 43.5% terpineol solvent, 43.5% dibutyl carbitol, 7.5% oleic acid, and 5.5% ethyl cellulose (49% ethoxyl content, viscosity: 0.02 Pa·s for a 5% solution in 80:20 toluene:ethanol), by weight. Then, a pre-paste mixture was formed by mixing: 693.8 g of the pre-wet aluminum slurry with 18.75 g of organic vehicle 2 (OV2); 3.75 g of epoxidized octyl tallate; 2.25 g of polyunsaturated oleic acid; and 7.5 g of a mixture of wax and hydrogenated castor oil. OV2 included 46.7% terpineol solvent, 40.9% dibutyl carbitol, and 12.4% ethyl cellulose (51% ethoxyl content, viscosity: 0.2 Pa·s for a 5% solution in 80:20 toluene:ethanol), by weight. The as prepared pre-paste mixture was divided into three portions and each portion was placed in a plastic jar of 250 g maximum capacity, and the contents of each jar were mixed for 30 sec at 2000 rpm using a planetary centrifugal mixer THINKY ARE-310 (Thinky USA, Inc., Laguna Hills, Calif.), followed by a period of cooling to ambient temperature. The centrifugal mixing and cooling was repeated for a total of three times for each jar. The three portions of the pre-paste mixture were then combined and the combined pre-paste A2 was dispersed at 1800 to 2200 rpm for three min using a high shear mixer, Dispermat® TU-02 (VMA-Gwetzmann GMBH, Reichshof, Germany). The pre-paste A2 was also stirred by hand to eliminate possible unmixed areas at the side, and the mixing with the Dispermat® TU-02 was repeated two more times to ensure uniformity.

The aluminum content of the pre-paste A2 was then measured in duplicate by weighing small quantities (3-5 g) into an alumina boat and firing in a muffle furnace at 450° C. for 30 min to remove organics, and reweighing to obtain the residual aluminum weight. The pre-paste A2 was found to have 74.4% aluminum by weight. The goal for the total solid content of the final paste was 74.0%. To achieve the desired wt % and viscosity range, 2.61 g of OV2 and 0.56 g of organic vehicle 3 (OV3) (a 50/50 blend of terpineol solvent and dibutyl carbitol) were added to 646.7 g of the pre-paste and mixed again using Dispermat® to obtain the master batch paste A2. The viscosity of the master batch paste A was measured the following day using a Brookfield HADV-I Prime viscometer with the thermally controlled small-sample adapter at 25° C. and was found to be 83 Pa·s at 10 rpm. The final solid content of the master batch paste A was found to be 74.6 wt %.

### Preparation of Master Batch Aluminum Pastes A1, B, C, D, and E

A similar procedure was used to make the other master batch pastes (A1, B, C, D, and E) using different alumnium powders (A, B, C, D, and E). Aluminum powder A was air-atomized nodular aluminum powder having average particle size of 6.9 microns; Aluminum powder B was nitrogen-atomized spherical aluminum powder having an average particle size of 6.2 microns; Aluminum powder C was nitrogen-atomized spherical aluminum powder having an average particle size of 7.3 microns; Aluminum powder D was nitrogen-atomized spherical aluminum powder having an average particle size of 2.9 microns. Aluminum powder E was nitrogen-atomized spherical aluminum powder having an average particle size of 10.4 microns. Also, differing quantities of OV2 and OV3 were used to adjust to the final solid content and viscosities. Table 1 summarizes the composition of various master batch aluminum pastes (A1, A2, B, C, D, and E).

TABLE 1
Composition of Master batch Aluminum Pastes

| | Master Batch Paste | | | | | |
|---|---|---|---|---|---|---|
| | A1 | A2 | B | C | D | E |
| Aluminum | A | A | B | C | D | E |
| powder | | | | | | |
| Wt % Al in | 80% | 80% | 80% | 84% | 80% | 80% |
| pre-wet Al | | | | | | |
| slurry of Al | | | | | | |
| and OV1 | | | | | | |
| Pre-wet Al | 693.8 | 693.8 | 234.4 | 228.5 | 240.5 | 249.50 |
| slurry (g) | | | | | | |
| Additional | 0 | 0 | 0 | 6.9 | 0 | 0 |
| OV1 (g) | | | | | | |
| OV2 (g) | 18.75 | 18.75 | 3.75 | 6.50 | 6.50 | 6.75 |
| Epoxidized | 3.75 | 3.75 | 1.25 | 1.30 | 1.30 | 1.36 |
| octyl tallate (g) | | | | | | |
| Oleic acid (g) | 2.25 | 2.25 | 0.75 | 0.80 | 0.80 | 0.84 |
| Wax/ | 7.5 | 7.5 | 2.375 | 2.60 | 2.60 | 2.71 |
| hydrogenated | | | | | | |
| castor oil (g) | | | | | | |
| Final Solid | 73.1% | 74.6% | 74.9% | 76.3% | 75.5% | 75.8% |
| wt % in the | | | | | | |
| Master Batch | | | | | | |
| Paste | | | | | | |
| Final Viscosity | 92 | 83 | 34 | 59 | 41 | 41 |
| of the Master | | | | | | |
| Batch Paste | | | | | | |
| (Pa · s) | | | | | | |

### Preparation of Master Batch Aluminum Paste F

Commercial aluminum paste PV322 (5 g) obtained from Microcircuit Materials, DuPont Inc. (Wilmington, Del.) and 5 g of aforementioned OV2 were mixed for 1 min at 2000 rpm using a planetary centrifugal mixer THINKY ARE-310, followed by a period of cooling to ambient temperature. This centrifugal mixing and cooling was repeated for a total of three times. The final solid content of the master batch paste F was estimated to be 36.6 wt %.

### Preparation of Additive Aluminum Pastes

Four siloxanes (S1, S2, S3, and S4) were used in the preparation of aluminum paste compositions. The siloxane S1 was poly(dimethylsiloxane-co-methylphenylsiloxane), Dow Corning® 550 fluid (125 cSt) and the siloxane S2 was poly(methylhydrogensiloxane), Dow Corning® 1107 fluid (30 cSt), both obtained from Dow Chemical Company (Midland, Mich.). The siloxane S3 was a copolymer of 75-85% ethylmethylsiloxane and 15-25% (alpha-methylphenylethyl)methylsiloxane, Gelest Apt-213 (1,200-1,600 cSt), obtained from GELEST Inc (Morrisville, Pa.). The siloxane S4 was polydimethylsiloxane, Dow Corning® 200 fluid in two viscosities, 10 cSt and 1000 cSt, obtained from Sigma-Aldrich, Inc., Milwaukee, Wis.

The number of silicon atoms present in each of the above siloxanes was estimated as follows:

For the siloxane S1, poly(dimethylsiloxane-co-methylphenylsiloxane), an equivalent product, PM-125, by Clearco Products (Bensalem, Pa.) having a viscosity of 125 cSt was found to have a molecular weight of 2100. Assuming 2100 as the molecular weight of S1 and an average molecular weight of 106 for the repeat units, S1 was estimated to have approximately 20 silicon atoms (n=20).

For the siloxane S2, poly(methylhydrogensiloxane), n was estimated to be 37 based on the reported value of n=37 for poly(methylhydrogensiloxane) having a viscosity of 30 cSt in Lipowitz, J. et al. Aldrichimica Acta, 1973, 6(1): p. 1-6.

For the siloxanes S3 and S4, first a relationship between density and kinematic viscosity for the oligomeric and the polymeric dimethylsiloxanes was established based on the densities supplied by Dow Corning for S3 and S4, and the works of Hunter, M. J. et al., Journal of the American Chemical Society, 1946, 68: p. 2284-2290; and Fletcher, H. J. et al., Journal of the American Chemical Society, 1949, 71: p. 2918-2922. Kataoka, T. et al., Journal of Polymer Science Part A-1, 1967, 5: p. 3071-3089, reported both dynamic viscosities and molecular weights of a series of polydimethylsiloxanes, and the above relationship was used to estimate the densities and then the kinematic viscosities of these polymers. Then, a relationship between molecular weight and kinematic viscosity was established. This relationship was used to estimate molecular weight and n for the listed viscosities by the manufacturer for S3 and S4. The molecular weight of the low-viscosity S4 was estimated to be 1,200 with n=16, and the molecular weight of the high-viscosity S4 was estimated to be 10,000 with n=135. Similarly, S3 was estimated to have molecular weight in the range of 12,000-15,000, and with the average molecular weight of 106 per repeat unit, the value of n for S3 was estimated to be in the range of 113-141.

Exemplary additive aluminum paste composition comprising 3% siloxane 51, by weight, based on the total Non-OV content (Al and S1 in this case), was made by mixing 0.339 g of siloxane S1 and 15.0 g of master batch paste A1 using a THINKY centrifugal mixer three times, for 30 sec at 2000 rpm speed each time, with cooling to ambient temperature in between the mixing. This exemplary paste is referred to herein as 3 wt % S1 additive paste and was used in making the solar cells of Examples 1 and 2 shown in Table 2.

For all paste compositions used herein to make solar cells for measuring electrical performance, wt % of the additive is based on the total Non-OV content of the aluminum paste composition. Hence, in Example 1, the paste contained 2.2 wt % of siloxane S1, and an Al:S1 ratio of 97:3, or 3.0 wt % siloxane S1 based on the sum of aluminum and siloxane S1; the paste is indicated as 3% siloxane S1 in the Table 2. Other additives, for example calcium pyrophosphate and frit were also used along with siloxane in the preparation of aluminum paste compositions.

Another exemplary additive aluminum paste composition comprising 0.6% siloxane S1, by weight, based on the total Non-OV content (A1 and S1 in this case), was prepared by mixing 3.00 g of 3 wt % S1 additive paste, prepared as above, with 12.0 g of master batch paste A1 using a THINKY centrifugal mixer three times, for 30 sec at 2000 rpm speed each time. This exemplary paste is referred to herein as 0.6 wt % S1 additive paste and was used for making the cells of Example 2.

For the additive aluminum paste used in Example 5, 57 mg of siloxane S1, 57 mg of the milled Ca₂P₂O₇, as described below, 94 mg of frit as prepared below, and 25.0 mg of master batch paste A2 were mixed using a THINKY centrifugal mixer three times, for 30 sec at 2000 rpm speed each time and high shear mixer DISPERMET® TU-02 three times at 1800 rpm to 2200 rpm for 3 min each time.

The additive aluminum paste used in Example 15 was made by mixing 6.25 g of master batch paste D, 18.75 g of master batch paste E, and 57 mg of siloxane S1, using a THINKY centrifugal mixer three times, for 30 sec at 2000 rpm speed each time and high shear mixer DISPERMET® TU-02 three times at 1800 rpm to 2200 rpm for 3 min each time. The resulting additive aluminum paste was then a mixture of 25% of master batch paste D (using aluminum D) and 75% master batch paste E (using aluminum E). This exemplary paste is referred to herein as 25D:75E S1 additive paste. Similarly, the exemplary paste for Example 21, refrerred to as 25A2:75 B in Table 2, used 25% of master batch A2 and 75% of master batch B.

Similar procedures were used to make other exemplary aluminum pastes comprising one or more master batch pastes (A1, A2, B, C, D, and E), siloxanes (S1, S2, or S3), and optional additional additives as detailed in Table 2.

The additive aluminum paste used in Example 22 was made by adding 5 g of PWAS into 1.87 g of S4 (viscosity: 10 cSt) using a high shear mixer, Dispermat® TU-02 at 2000 rpm for 1 minute to form a pre-paste. The pre-paste was then mixed with 5.0 g of S4 (viscosity: 1000 cSt) using a THINKY centrifugal mixer three times, for 60 sec at 2000 rpm speed each time with a period of cooling to ambient temperature in between the mixing. The resulting additive aluminum paste comprised 58% siloxane S4, by weight, 8.4% OV1, and 33.7% aluminum, based on the total Non-OV content (A1 and S4 in this case). This exemplary paste is referred to herein as 58 wt % S4 additive paste.

### Milling of Calcium Pyrophosphate (Ca₂P₂O₇)

Calcium pyrophosphate (Ca₂P₂O₇) (10 g) obtained from Sigma-Aldrich (St. Louis, Mo., USA) was milled using 26 g of isopropanol (IPA) and 205 g of yittria-stabilized zirconia (YSZ) milling media of 5 mm size on a jar mill (US Stoneware, East Palestine, Ohio) at 80 rpm for 70 hours. The milled calcium pyrophosphate was separated from the isopropanol in a centrifuge (Swinging-bucket Damon IEC Model K, Thermo-Electron, Waltham, Mass., USA) at 3000 rpm for 90 min. The powdered calcium pyrophosphate was dried in a vacuum oven at ambient temperature overnight. The particle size of the calcium pyrophosphate powder was measured using laser light scattering (model LA-910, Horiba Instruments, Irvine, Calif., USA) to be a d₅₀ of 0.8 microns.

### Frit Preparation

Frit (50 g) of was made by heating a mixture of bismuth(III) oxide (23.1 g), silicon dioxide (8.89 g), diboron trioxide (7.9 g), antimony trioxide (6.20 g), and zinc oxide (3.91 g) in a platinum crucible to 1400° C. in air in a box furnace (CM Furnaces, Bloomfield, N.J.). The liquid was poured out of the crucible onto a metal plate to quench it. XRD analysis indicated that the frit was amorphous. The frit was milled in IPA using 5 mm YSZ balls with the jar mill, reducing the particles to a d₅₀ of 0.53 microns.

### Formation of Exemplary Solar Cells 1-21 and Comparative Solar Cells A and B

Exemplary solar cells were fabricated starting with p-type polycrystalline silicon wafers having an average thickness of 150 microns or 165 microns. The silicon wafers had a base resistivity of 1 Ohm/sq, an emitter resistivity of 65 Ohm/sq, and a hydrogen containing silicon nitride (SiNₓ:H) antireflective coating formed by plasma enhanced chemical vapor deposited (PECVD). The 152 mm×152 mm silicon wafers were cut into smaller 28 mm×28 mm wafers using a diamond saw, and then cleaned.

Master batch aluminum pastes A1, A2 and additive pastes prepared supra were printed onto the back side of the silicon wafers using a screen (Sefar Inc., Depew, N.Y.) with a square opening of 26.99 mm×26.99 mm and a screen printer model MSP 885 (Affiliated Manufacturers Inc., North Branch, N.J.). The screens for printing aluminum paste used an 8″×10″ frame, 230 mesh wires of 136 microns diameter at 30° angle, and a 13 micron thick dual cure emulsion of the polyvinyl acetate/polyvinyl alcohol/diazo type (Sefar e-11). This left a 0.5 mm border of bare Si (i.e., without Al paste) around the edges. Each wafer was weighed before and after the application of aluminum paste to determine a net weight of applied aluminum paste on the silicon wafer. The wet weight of Al paste was targeted to be 55 mg, which produced an Al loading after firing of 5.6 mg Al/cm². The silicon wafers with aluminum paste were dried in a mechanical convection oven with vented exhaust for 30 min at 150° C. resulting in a dried film thickness of 30 μm.

Then, a silver paste Solamet® PV159 (E. I. du Pont de Nemours and Company, Wilmington, Del.) was screen printed using screens on 8″×10″ frames (Sefar Inc., Depew, N.Y.) and a screen printer model MSP 485 (Affiliated Manufacturers Inc., North Branch, N.J.) on the silicon nitride layer on the front surface of the silicon wafer and dried at 150° C. for 20 min in a convection oven to give 20 microns thick silver grid lines and a bus bar. The screen printed silver paste had a pattern of eleven fingers/grid lines of 100 microns width connected to a bus bar of 1.25 mm width located near one edge of the cell. The screen for printing the silver paste used 325-mesh wires of 23 microns diameter at 30° and 31 microns thick emulsion.

All of the exemplary and comparative solar cells were made in groupings denoted as “series”, X1-X8. Within a series all of the solar cells were printed with the aluminum pastes and the silver paste on the same day and, with the exception of the cells of Sample 14, were fired together on the same or at a later day.

The silicon wafers, with aluminum and silver pastes printed on them and dried, for Comparative Examples A, B and Examples 1-8 and 14, shown in Table 2, were fired in an IR furnace PV614 reflow oven (Radiant Technology Corp., Fullerton, Calif.) at a belt speed of 457 cm/minute (or 180 inch/minute). The furnace had six heated zones, and the zone temperatures used were zone 1 at 550° C., zone 2 at 600° C., zone 3 at 650° C., zone 4 at 700° C., zone 5 at 800° C., and the final heated zone 6 set at peak temperature, Tₘₐₓ, in the range of 840-940° C. The wafers took 33 sec to pass through all of the six heated zones with 2.5 sec each in zone 5 and the zone 6. The wafers reached peak temperatures lower than the zone 6 set, in the range of 740-840° C.

After printing and drying the aluminum and silver pastes, the silicon wafers for Examples 9-13 and 15-21, shown in Table 2 were fired in a O-zone furnace (BTU International, North Billerica, Mass.; Model PV309) at a belt speed of 221 cm/minute (or 87 inch/minute) with zone temperatures set as zone 1 at 610° C., zone 2 at 610° C., zone 3 at 585° C., and the final zone 4 set at peak temperature, Tₘₐₓ, in the range of 860° C. to 940° C. The wafers took 5.2 sec to pass through zone 4.

For each furnace, only the temperature Tₘₐₓ of the last zone (zone 6 for the IR furnace and zone 4 for the BTU furnace) was varied and is reported as the cell firing temperature in Table 2. After firing the silicon wafers (which had aluminum and silver pastes printed and dried) in the 6-zone or 4-zone furnaces, the metalized wafers became functional photovoltaic devices. Table 2 summarizes the exemplary solar cells (1-22) and comparative solar cells (A-B) which were formed and for which electrical characteristics were subsequently measured.

TABLE 2
Solar cells formed using aluminum paste
compositions with and without additives

| | Back-side Paste (wt % based on the | | | |
|---|---|---|---|---|
| | total Non-OV content) | | | |
| | | Other | | Firing |
| Example | | additives | | Temperature |
| # | Master batch and siloxane | Ca₂P₂O₇ | Frit | (° C.) |
| Control | Paste A1 | — | — | 900 |
| A | | | | |
| 1 | Paste A1 with 3% S1 | — | — | 900 |
| 2 | Paste A1 with 0.6% S1 | — | — | 875 |
| Control | Paste A2 | — | — | 910 |
| B | | | | |
| 3 | Paste A2 with 0.1% S1 | — | — | 860 |
| 4 | Paste A2 with 0.3% S1 | — | — | 885 |
| 5 | Paste A2 with 0.3% S1 | 0.3% | 0.3% | 860 |
| 6 | Paste A2 with 0.3% S2 | — | — | 860 |

Series X4

| | | | | |
|---|---|---|---|---|
| 7 | Paste A2 with 0.3% S3 | — | — | 880 |
| 8 | Paste B with 0.1% S1 | — | — | 840 |
| 9 | Paste A2 with 0.3% S1 | 0.03 | 0.03 | 920 |
| 10 | Paste A2 with 0.01% S1 | 0.03 | 0.3 | 900 |
| 11 | Paste A2 with 0.01% S1 | 0.3 | 0.03 | 920 |
| 12 | Paste A2 with 0.3% S1 | 0.3 | 0.3 | 900 |
| 13 | Paste A2 with 0.06% S1 | 0.1 | 0.1 | 900 |
| 14 | Paste A2 with 0.06% S1 | 0.1 | 0.1 | 900 |
| 15 | Paste 25D:75E with 0.3% | — | — | 900 |
| | S1 | | | |
| 16 | Paste 25D:75E with 0.3% | — | — | 935 |
| | S3 | | | |
| 17 | Paste 25D:75E with 0.3% | — | 0.3% | 915 |
| | S1 | | | |
| 18 | Paste 25D:75E with 0.3% | — | 0.3% | 915 |
| | S3 | | | |
| 19 | Paste A2 with 0.3% S1 | — | 0.3% | 915 |
| 20 | Paste A2 with 0.3% S3 | — | 0.3% | 915 |
| 21 | Paste 25A2:75B with 0.3% | — | 0.3% | 915 |
| | S3 | | | |

### Formation of Exemplary Solar Cell 22 and Comparative Solar Cell C

Comparative solar cell C was made by screen printing the master batch aluminum paste F onto the back side of a silicon wafer and screen printing a silver paste Solamet® PV145 (E. I. du Pont de Nemours and Company, Wilmington, Del.) on the silicon nitride layer on the front surface of the silicon wafer. This wafer will be referred to herein as wafer C.

Similarly, exemplary solar cell 22 was made by screen printing the 58 wt % S4 additive paste onto the back side of a silicon wafer and screen printing a silver paste Solamet® PV145 (E. I. du Pont de Nemours and Company, Wilmington, Del.) on the silicon nitride layer on the front surface of the silicon wafer, using the procedure described supra. This wafer will be referred to herein as wafer 22.

The wet weight of Al paste was targeted to be ˜55 mg, which produced an estimated Al loading after firing of 2.9 mg Al/cm².

To minimize mud-cracking of the printed Al back contact, the printed wafers C and 22 were dried by slowly ramping the temperature to 150° C. in 60 min and then holding it at 150° C. for another 30 min. The printed and dried wafers C and 22 were then fired in a Rapid Thermal Processing System, RTP-6005 (Modular Process Technology Corp., San Jose, Calif.) using the following temperature profile: heated from room temperature (˜25° C.) to 580° C. in 30 sec, held at 580° C. for 10 sec, ramped to a peak temperature, Tₘₐₓ, of 740° C. in 10 sec, held at 740° C. for 2 sec, and finally turn off power to cool down to room temperature to form comparative solar cell C and exemplary solar cell 22. Ambient air atmosphere was used throughout the firing cycle.

### Evaluation of the Electrical Performance of Solar Cells Prepared Supra

A commercial Current-Voltage (JV) tester ST-1000 (Telecom-STV Ltd., Moscow, Russia) was used to make efficiency measurements of the polycrystalline silicon photovoltaic cells. Two electrical connections, one for voltage and one for current, were made on the top and the bottom of each of the photovoltaic cells. Transient photo-excitation was used to avoid heating the silicon photovoltaic cells and to obtain JV curves under standard temperature conditions (25° C.). A flash lamp with a spectral output similar to the solar spectrum illuminated the photovoltaic cells from a vertical distance of 1 m. The lamp power was held constant for 14 milliseconds. The intensity at the sample surface, as calibrated against external solar cells was 1000 W/m² (or 1 Sun) during this time period. During the 14 milliseconds, the JV tester varied an artificial electrical load on the sample from short circuit to open circuit. The JV tester recorded the light-induced current through, and the voltage across, the photovoltaic cells while the load changed over the stated range of loads. A power versus voltage curve was obtained from this data by taking the product of the current times the voltage at each voltage level. The maximum of the power versus voltage curve was taken as the characteristic output power of the solar cell for calculating solar cell efficiency. This maximum power was divided by the area of the sample to obtain the maximum power density at 1 Sun intensity. This was then divided by 1000 W/m² of the input intensity to obtain the efficiency which is then multiplied by 100 to present the result in percent efficiency. Other parameters of interest were also obtained from this same current-voltage curve. Of special interest were the open circuit voltage (U_{oc} in mV), the voltage where the current is zero, the short circuit current (I_{sc} in mA) which is the current when the voltage is zero, and, fill factor (FF in %).

Each aluminum paste typically gave an efficiency which became maximized at a firing temperature which was different for the different pastes. For each paste within a Series, a number of duplicate photovoltaic cells were fabricated. These photovoltaic cells were then divided into 3 or 4 groups, and all the photovoltaic cells in each group (typically 3-6 wafers per group) were fired at the same temperature. The firing temperatures for the different groups were increased in increments of 20-25° C. For each firing temperature, the median efficiency of the photovoltaic cells in that group was determined. The firing temperature which gave the maximum median efficiency for that aluminum paste was selected and reported in the Table 3. Table 3 also lists the median values of Eff, U_{oc}, I_{sc}, and FF obtained for the cells fired at the temperature listed.

TABLE 3
Electrical performance of solar cells

| | | | | | |
|---|---|---|---|---|---|
| Example | Back-side Paste (wt % based on the | Median | Median | Median | Median |
| # | total Non-OV content) | Efficiency (%) | Uoc (mV) | Isc (mA) | FF (%) |

Series X1

| | | | | | |
|---|---|---|---|---|---|
| Control | Paste A1 | 14.20 | 600.0 | 247.0 | 74.5 |
| A | | | | | |
| 1 | Paste A1 with 3% S1 | 14.29 | 600.0 | 244.0 | 76.4 |

Series X2

| | | | | | |
|---|---|---|---|---|---|
| Control | Paste A2 | 14.36 | 603.0 | 248.0 | 74.8 |
| B | | | | | |
| 3 | Paste A2 with 0.1% S1 | 14.46 | 608.0 | 247.5 | 75.1 |
| 4 | Paste A2 with 0.3% S1 | 14.59 | 605.0 | 247.0 | 75.4 |

Series X3

| | | | | | |
|---|---|---|---|---|---|
| 5 | Paste A2 with 0.3% S1, | 14.97 | 603.0 | 256.0 | 75.7 |
| | 0.3% Ca₂P₂O₇ and 0.3% Frit | | | | |
| 6 | Paste A2 with 0.3% S2 | 14.70 | 606.0 | 254.0 | 74.1 |

Series X4

| | | | | | |
|---|---|---|---|---|---|
| 7 | Paste A2 with 0.3% S3 | 14.75 | 605.0 | 246.0 | 77.3 |

Series X5

| | | | | | |
|---|---|---|---|---|---|
| 8 | Paste B with 0.1% S1 | 14.52 | 605.5 | 245.0 | 75.7 |

Series X6

| | | | | | |
|---|---|---|---|---|---|
| 9 | Paste A2 with 0.3% S1, | 14.86 | 608.0 | 249.0 | 76.1 |
| | 0.03% Ca₂P₂O₇ and 0.03% Frit | | | | |
| 10 | Paste A2 with 0.01% S1, | 14.84 | 609.0 | 249.0 | 76.2 |
| | 0.03% Ca₂P₂O₇ and 0.3% Frit | | | | |
| 11 | Paste A2 with 0.01% S1, | 14.35 | 603.5 | 247.5 | 74.8 |
| | 0.3% Ca₂P₂O₇ and 0.03% Frit | | | | |
| 12 | Paste A2 with 0.3% S1, | 14.61 | 608.0 | 249.0 | 75.6 |
| | 0.3% Ca₂P₂O₇ and 0.3% Frit | | | | |
| 13 | Paste A2 with 0.06% S1, | 14.70 | 610.5 | 249.0 | 75.9 |
| | 0.1% Ca₂P₂O₇ and 0.1% Frit | | | | |
| 14 | Paste A2 with 0.06% S1, | 14.99 | 606.5 | 250.0 | 76.7 |
| | 0.1% Ca₂P₂O₇ and 0.1% Frit | | | | |

Series X7

| | | | | | |
|---|---|---|---|---|---|
| 15 | Paste 25D:75E with 0.3% S1 | 14.05 | 599.0 | 239.0 | 75.5 |
| 16 | Paste 25D:75E with 0.3% S3 | 14.05 | 600.0 | 242.0 | 74.3 |

Series X8

| | | | | | |
|---|---|---|---|---|---|
| 17 | Paste 25D:75E with 0.3% S1 | 14.49 | 604.0 | 240.5 | 77.7 |
| | and 0.3% Frit | | | | |
| 18 | Paste 25D:75E with 0.3% S3 | 13.75 | 599.0 | 241.0 | 74.3 |
| | and 0.3% Frit | | | | |
| 19 | Paste A2 with 0.3% S1 and | 14.51 | 605.5 | 243.5 | 77.0 |
| | 0.3% Frit | | | | |
| 20 | Paste A2 with 0.3% S3 and | 14.58 | 609.0 | 246.0 | 76.4 |
| | 0.3% Frit | | | | |
| 21 | Paste 25A2:75B with 0.3% S3, | 14.30 | 604.5 | 243.0 | 76.0 |
| | and 0.3% Frit | | | | |

Table 3 shows that in series X1, the group of cells for Examples 1 and 2, formed using Al pastes comprising siloxane S1 gave higher efficiency than the Comparative Example A with no siloxane. In these cells, the backside contained visible round nodules of Al, each significantly larger than the original particles of Al in the paste. The subsequent Examples 3-21, which used lower concentrations of siloxane and in some cases additional additives, did not display these round nodules of aluminum. In Series X2, the group of cells for the Examples 3 and 4 formed using Al pastes comprising siloxane S1 gave cells with higher Eff and U_{oc} than the Comparative Example B with no siloxane.

The median efficiency of Examples 9-13 were analyzed using the methods of Design of Experiments with Minitab software. For this combination of three additives (S1, Ca₂P₂O₇, and Frit) and nodular aluminum, the main effect of siloxane S1 and frit was to increase efficiency and that of the phosphate was to decrease efficiency.

The results of Series X7 indicated that without frit and with the 25D:75E aluminum powder mixture, there was a small or no difference between the efficiency provided by siloxanes S1 and S3. In Series X8 with 0.3% frit additive, there was little difference in the efficiencies using the different aluminum powders and siloxanes, with the exception of the combination of S3 and the 25D:75E aluminum powder mixture gave lower efficiency.

The electrical properties of the comparative solar cell C and the exemplary solar cell 22 were measured using the procedure described above. Table 4 reports Eff, U_{oc}, I_{sc}, FF, and series resistance for single cells fired at 740° C. and no optimization of firing temperature was performed.

TABLE 4
Electrical performance of solar cells

| | Back-side | | | | | |
|---|---|---|---|---|---|---|
| | Paste (wt % | | | | | |
| | based on the | | | | | Series |
| Example | total Non-OV | Efficiency | Uoc | Isc | FF | Resistance |
| # | content) | (%) | (mV) | (mA) | (%) | (ohm) |
| C | Paste F | 10.97 | 569.0 | 217.0 | 69.4 | 0.2717 |
| 22 | Aluminum | 11.31 | 577.0 | 225.0 | 67.7 | 0.2903 |
| | powder A | | | | | |
| | with 58% S4 | | | | | |

The results in Table 4 clearly demonstrates that aluminum paste comprising siloxane S4 can be used to form a solar cell with similar or better electrical performance as compared to a solar cell made with commercial Aluminum paste, both having similar amount of aluminum content. In particular, it is worth noting that the presence of siloxane in the aluminum paste did not create deleterous defects that often lowers Uoc and/or Isc.

What is claimed is:

1. An aluminum paste composition consisting essentially of:
(a) 0.005-2.6%, by weight of at least one siloxane;
(b) 44.5-84.9%, by weight of an aluminum powder, such that the weight ratio of aluminum powder to siloxane is in the range of about 30:1 to about 10,000:1;
(c) 0.01-6.8%, by weight of an optional indium-free additive, wherein the optional indium-free additive comprises lead-free glass frit, amorphous silicon dioxide, organometallic compounds, boron-containing compounds, metal salts, or mixtures thereof; and
(d)15-50%, by weight of an organic vehicle,
wherein the amounts in % by weight are based on the total weight of the aluminum paste composition.

2. The aluminum paste composition of claim 1, wherein the siloxane comprises at least one of a monofunctional “M” unit having the formula, RR′R″SiO_{1/2}; a difunctional “D” unit having the formula, R¹R²SiO_{2/2}; or a trifunctional “T” unit having the formula, R³SiO_{3/2},
wherein R, R′, R″, R², and R³ denote hydrocarbyl groups or substituted hydrocarbyl groups, and R¹ is at least one of a hydrogen, a hydrocarbyl group, or a substituted hydrocarbyl group.

3. The aluminum paste composition of claim 2, wherein the siloxane is at least one of a linear siloxane having the formula, M-Dₙ₋₂-M; a cyclic siloxane having the formula, Dₙ; or a branched siloxane having the formula, TₖDₘM₂₊ₖ, where k (k≧1) is the number of branches, m (m≧0) is the number of difunctional units, and the total number of silicon atoms (n) in the branched siloxane is n=2+2k+m, and
wherein n, the total number of silicon atoms, is in the range of 2-300.

4. The aluminum paste composition of claim 3, wherein n is in the range of 2-80.

5. The aluminum paste composition of claim 1, wherein the siloxane comprises at least one of poly(dimethylsiloxane), poly(methylhydrogensiloxane), poly(dimethylsiloxane-co-methylphenylsiloxane), poly(ethylmethylsiloxane-co-(alpha-methylphenylethyl)methylsiloxane), and mixtures thereof.

6. The aluminum paste composition of claim 1, wherein the lead-free glass frit comprises at least 10%, by weight of one of a bismuth oxide, an antimony oxide, or a mixture thereof.

7. The aluminum paste composition of claim 1, wherein the siloxane is present in an amount ranging from 0.035-0.51%, by weight, such that the weight ratio of aluminum powder to siloxane is in the range of about 152:1 to about 2,000:1.

8. A process of forming a silicon solar cell comprising:
(a) applying an aluminum paste on a back-side of a p-type silicon substrate, the aluminum paste consisting essentially of 0.005-2.6%, by weight of a siloxane; 44.5-84.9%, by weight of an aluminum powder, such that the weight ratio of aluminum powder to siloxane is in the range of about 30:1 to about 10,000:1; 0.01-6.8%, by weight of an optional indium-free additive, wherein the optional indium-free additive comprises lead-free glass frit, amorphous silicon dioxide, organometallic compounds, boron-containing compounds, metal salts, or mixtures thereof; and 15-50%, by weight of an organic vehicle, wherein the amounts in % by weight are based on the total weight of the aluminum paste composition;
(b) applying a metal paste on a front-side of the p-type silicon substrate, the front-side being opposite to the back-side; and
(c) firing the p-type silicon substrate after the application of both the aluminum paste and the metal paste to a peak temperature of Tₘₐₓ in the range of 600-980° C., such that the substrate is fired at the temperature range of (Tₘₐₓ-100)−Tₘₐₓ for 0.4-30 sec.

9. The process of forming a silicon solar cell according to claim 8, wherein the siloxane comprises at least one of a monofunctional “M” unit having the formula, RR′R″SiO_{1/2}; a difunctional “D” unit having the formula, R¹R²SiO_{2/2}; or a trifunctional “T” unit having the formula, R³SiO_{3/2},
wherein R, R′, R″, R², and R³ denote hydrocarbyl groups or substituted hydrocarbyl groups, and R¹ is at least one of a hydrogen, a hydrocarbyl group, or a substituted hydrocarbyl group.

10. The process of forming a silicon solar cell according to claim 9, wherein the siloxane is at least one of a linear siloxane having the formula, M-Dₙ₋₂-M; a cyclic siloxane having the formula, Dₙ; or a branched siloxane having the formula, TₖDₘM₂₊ₖ, where k (k≧1) is the number of branches, m (m≧0) is the number of difunctional units, and the total number of silicon atoms (n) in the branched siloxane is n=2+2k+m, and
wherein n, the total number of silicon atoms is in the range of 2-300.

11. The process of forming a silicon solar cell according to claim 8, wherein the siloxane comprises at least one of poly(dimethylsiloxane), poly(methylhydrogensiloxane), poly(dimethylsiloxane-co-methylphenylsiloxane), poly(ethylmethylsiloxane-co-(alpha-methylphenylethyl)methylsiloxane), or mixtures thereof.

12. The process of forming a silicon solar cell according to claim 8, wherein the lead-free glass frit comprises at least 10%, by weight of one of a bismuth oxide, an antimony oxide, or a mixture thereof.

13. The process of forming a silicon solar cell according to claim 8, wherein the siloxane is present in an amount ranging from 0.035-0.51%, by weight, such that the weight ratio of aluminum powder to siloxane is in the range of 152:1 to 2,000:1.

14. The process of forming a silicon solar cell according to claim 8, wherein the step of applying the aluminum paste on a back-side of a p-type silicon substrate comprises:
(a) screen printing the aluminum paste on the back-side of the p-type silicon substrate;
(b) drying the aluminum paste at a temperature in the range of 100-175° C. for 5-60 min or in the range of 175-350° C. for 15-300 sec.

15. A silicon solar cell made by the process of claim 8.

16. An aluminum paste composition comprising:
(a)15-68%, by weight of at least one siloxane;
(b)25-84.9%, by weight of an aluminum powder;
(c) 0.1-10%, by weight of an organic vehicle,
wherein the amounts in % by weight are based on the total weight of the aluminum paste composition.

17. The aluminum paste composition of claim 16, wherein the siloxane comprises at least one of a monofunctional “M” unit having the formula, RR′R″SiO_{1/2}; a difunctional “D” unit having the formula, R¹R²SiO_{2/2}; or a trifunctional “T” unit having the formula, R³SiO_{3/2},
wherein R, R′, R″, R², and R³ denote hydrocarbyl groups or substituted hydrocarbyl groups, and R¹ is at least one of a hydrogen, a hydrocarbyl group, or a substituted hydrocarbyl group.

18. The aluminum paste composition of claim 17, wherein the siloxane is at least one of a linear siloxane having the formula, M-Dₙ₋₂-M; a cyclic siloxane having the formula, Dₙ; or a branched siloxane having the formula, TₖDₘM₂₊ₖ, where k (k≧1) is the number of branches, m (m≧0) is the number of difunctional units, and the total number of silicon atoms (n) in the branched siloxane is n=2+2k+m, and
wherein n, the total number of silicon atoms is in the range of 2-300.

19. The aluminum paste composition of claim 18, wherein n is in the range of 15-140.

20. The aluminum paste composition of claim 16, wherein the siloxane comprises at least one of poly(dimethylsiloxane), poly(methylhydrogensiloxane), poly(dimethylsiloxane-co-methylphenylsiloxane), poly(ethylmethylsiloxane-co-(alpha-methylphenylethyl)methylsiloxane), or mixtures thereof.

21. The aluminum paste composition of claim 16, wherein the siloxane is present in an amount ranging from 20-60%, by weight.

22. The aluminum paste composition of claim 16, further comprising an optional indium-free additive wherein the optional indium-free additive comprises lead-free glass frit, amorphous silicon dioxide, organometallic compounds, boron-containing compounds, metal salts, or mixtures thereof.

23. The aluminum paste composition of claim 22, wherein the lead-free glass frit comprises at least 10%, by weight of one of a bismuth oxide, an antimony oxide, or a mixture thereof.

24. A process of forming a silicon solar cell comprising:
(a) applying an aluminum paste on a back-side of a p-type silicon substrate, the aluminum paste comprising 15-68%, by weight of a siloxane; 25-84.9%, by weight of an aluminum powder; and 0.1-10%, by weight of an organic vehicle, wherein the amounts in % by weight are based on the total weight of the aluminum paste composition;
(b) applying a metal paste on a front-side of the p-type silicon substrate, the front-side being opposite to the back-side; and
(c) firing the p-type silicon substrate after the application of both the aluminum paste and the metal paste to a peak temperature of Tₘₐₓ in the range of 600-980° C., such that the substrate is fired at the temperature range of (Tₘₐₓ-100)−Tₘₐₓ for 0.4-30 sec.

25. The process of forming a silicon solar cell according to claim 24, wherein the siloxane comprises at least one of a monofunctional “M” unit having the formula, RR′R″SiO_{1/2}; a difunctional “D” unit having the formula, R¹R²SiO_{2/2}; or a trifunctional “T” unit having the formula, R³SiO_{3/2},
wherein R, R′, R″, R², and R³ denote hydrocarbyl groups or substituted hydrocarbyl groups, and R¹ is at least one of a hydrogen, a hydrocarbyl group, or a substituted hydrocarbyl group.

26. The process of forming a silicon solar cell according to claim 25, wherein the siloxane is at least one of a linear siloxane having the formula, M-Dₙ₋₂-M; a cyclic siloxane having the formula, Dₙ; or a branched siloxane having the formula, TₖDₘM₂₊ₖ, where k (k≧1) is the number of branches, m (m≧0) is the number of difunctional units, and the total number of silicon atoms (n) in the branched siloxane is n=2+2k+m, and
wherein n, the total number of silicon atoms is in the range of 2-300.

27. The process of forming a silicon solar cell according to claim 24, wherein the siloxane comprises at least one of poly(dimethylsiloxane), poly(methylhydrogensiloxane), poly(dimethylsiloxane-co-methylphenylsiloxane), poly(ethylmethylsiloxane-co-(alpha-methylphenylethyl)methylsiloxane), or mixtures thereof.

28. The process of forming a silicon solar cell according to claim 24, wherein the siloxane is present in an amount ranging from 15-68%, by weight.

29. The process of forming a silicon solar cell according to claim 24, wherein the aluminum paste further comprises an optional indium-free additive wherein the optional indium-free additive comprises lead-free glass frit, amorphous silicon dioxide, organometallic compounds, boron-containing compounds, metal salts, or mixtures thereof.

30. The process of forming a silicon solar cell according to claim 29, wherein the lead-free glass frit comprises at least 10%, by weight of one of a bismuth oxide, an antimony oxide, or a mixture thereof.

31. The process of forming a silicon solar cell according to claim 24, wherein the step of applying the aluminum paste on a back-side of a p-type silicon substrate comprises:
(a) screen printing the aluminum paste on the back-side of the p-type silicon substrate;
(b) drying the aluminum paste by ramping the temperature from room temperature to a drying temperature in the range of 100-200° C. at a ramp-rate in the range of 2-50° C./min and holding the temperature constant at the drying temperature for 1-60 min.

32. A silicon solar cell made by the process of claim 24.
